(19) United States
(12) Patent Application Publication
(10) Pub. No.: US 2019/0359842 A1
(43) Pub. Date: Nov. 28, 2019

(54) Electrically Conductive Composition

(71) Applicant: The Yokohama Rubber Co., LTD., Minato-ku, Tokyo (CN)

(72) Inventors: Kazuo Arakawa, Hiratsuka-shi, Kanagawa (JP); Takeaki Saiki, Hiratsuka-shi, Kanagawa (JP); Kazunori Ishikawa, Hiratsuka-shi, Kanagawa (JP)

(21) Appl. No.: 16/481,448

(22) PCT Filed: Jan. 23, 2018
(86) PCT No.: PCT/JP2018/002020

§ 371 Date: Jul. 26, 2019

(30) Foreign Application Priority Data
Jan. 26, 2017 (JP) 2017-011960

(51) Int. Cl. C09D 11/52; C09D 11/037; C09D 11/102; H01B 1/22

(52) U.S. Cl. CPC C09D 11/52; C09D 11/037; H01L 31/022425; H01B 1/22; C09D 11/102

(57) ABSTRACT

The present technology provides an electrically conductive composition comprising: electrically conductive particles; an epoxy resin A that is solid at 25° C. with an epoxy equivalent weight of 400 g/eq to 1500 g/eq, or an epoxy resin D that is solid at 25° C. with an epoxy equivalent weight of 1500 g/eq to 3500 g/eq; an epoxy resin B that is liquid at 25° C. with an epoxy equivalent weight of less than 400 g/eq; a curing agent C; and a solvent. A total amount of A, B, and C is 3-10 parts by mass per 100 parts by mass of the electrically conductive particles, or a total amount of D, B, and C is 3-6 parts by mass per 100 parts by mass of the electrically conductive particles. A mass ratio [(A or D)/B] is from 20/80 to 80/20, and a mass ratio [C/{(A or D)+B}] is from 2/98 to 10/90.

### FIELD OF THE TECHNOLOGY

The present technology relates to an electrically conductive composition.

### BACKGROUND ART

The use of electrically conductive pastes containing electrically conductive particles and epoxy resins to form electrodes in solar cells and the like has been previously proposed (e.g., Japan Patent Nos. 4413700 and 5277844).

Electrically conductive pastes are required to exhibit, inter alia, screen printability, low resistance of the obtained cured product, and excellent adhesion to the substrate. In solar cell finger electrode applications in particular, attempts have been made to widen the light-receiving surface area in order to improve the power generation efficiency. Measures to develop finer lines of fingers are being sought for the purpose of widening the light-receiving surface area, but in order to suppress an increase in resistance in association with the finer lines, a reduction in the resistance of the paste itself along with wiring printability with a high aspect ratio that increases the height with respect to the width of the wiring are simultaneously demanded. Techniques such as double printing in which printing is implemented twice in an overlapped manner have been proposed for the purpose of obtaining wiring with a high aspect ratio. However, in addition to requiring that printing and drying steps be implemented twice, such techniques also require an excessive amount of production line equipment such as printers and driers, and therefore result in significant disadvantages in line tact and manufacturing costs. Furthermore, in association with finer lines, high printing accuracy of overlapped printing is required, and the occurrence of issues such as misalignment is problematic.

### SUMMARY

The present technology provides an electrically conductive composition having: excellent screen printability including the formation of high aspect ratio wiring, low resistance, and adhesion to a substrate.

The present inventors discovered that a desired effect can be obtained with an electrically conductive composition containing electrically conductive particles, epoxy resins, and a curing agent by using a solid epoxy resin A or D in combination with a liquid epoxy resin B, the resins having different epoxy equivalent weights, and setting the content of each epoxy resin and other components to be within prescribed ranges.

The present technology provides the following configurations.

1. An electrically conductive composition containing:

electrically conductive particles;

an epoxy resin A that is a solid at 25° C. and has an epoxy equivalent weight of from 400 g/eq to less than 1500 g/eq, or an epoxy resin D that is a solid at 25° C. and has an epoxy equivalent weight of from 1500 g/eq to less than 3500 g/eq;

an epoxy resin B that is a liquid at 25° C. and has an epoxy equivalent weight of less than 400 g/eq;

a curing agent C; and

a solvent;

a total amount 1 of the epoxy resin A, the epoxy resin B, and the curing agent C being from 3 parts by mass to 10 parts by mass per 100 parts by mass of the electrically conductive particles, or a total amount 2 of the epoxy resin D, the epoxy resin B, and the curing agent C being from 3 parts by mass to less than 6 parts by mass per 100 parts by mass of the electrically conductive particles;

a mass ratio [(A or D)/B] of the epoxy resin A or the epoxy resin D to the epoxy resin B being from 20/80 to 80/20; and

a mass ratio [C/{(A or D)+B}] of the curing agent C to a total amount of the epoxy resin A or the epoxy resin D and the epoxy resin B being from 2/98 to 10/90.

2. The electrically conductive composition according to 1 above, wherein a softening point of the epoxy resin A is lower than 115° C.

3. The electrically conductive composition according to 1 or 2 above, wherein a softening point of the epoxy resin D is from 115° C. to 150° C.

4. The electrically conductive composition according to any one of 1 to 3 above, wherein a viscosity at 25° C. of the epoxy resin B is from 15 to 5000 mPa·s.

5. The electrically conductive composition according to any one of 1 to 4 above, wherein the electrically conductive particles are at least one type selected from the group consisting of silver powder, copper powder, and silver coated electrically conductive powder coated with silver on at least a portion of a surface.

6. The electrically conductive composition according to any one of 1 to 5 above, wherein the electrically conductive particles include flake-shaped particles E having a specific surface area of from 0.2 to 1.0 m²/g and spherical particles F having a specific surface area of from 0.5 to 1.6 m²/g; and

an average specific surface area of the electrically conductive particles is from 0.5 to 0.8 m²/g.

7. The electrically conductive composition according to any one of 1 to 6 above, wherein the total amount 1 is from 3 to 7.0 parts by mass per 100 parts by mass of the electrically conductive particles, or the total amount 2 is from 5.0 to 5.4 parts by mass per 100 parts by mass of the electrically conductive particles.

8. The electrically conductive composition according to any one of 1 to 6 above, wherein the epoxy resin B is only a polyhydric alcohol glycidyl-type epoxy resin, and

the total amount 2 is from 4.0 to 5.4 parts by mass per 100 parts by mass of the electrically conductive particles.

The electrically conductive composition of an embodiment of the present technology excels in screen printability, low resistance, and adhesion to a substrate.

### DETAILED DESCRIPTION

Embodiments of the present technology are described in detail below.

Note that in the present specification, numerical ranges indicated using “(from) . . . to . . . ” include the former number as the lower limit value and the latter number as the upper limit value.

In the present specification, unless otherwise noted, a single corresponding substance may be used for each component, or a combination of two or more types of corresponding substances may be used for each component. When a component contains two or more types of substances, the content of the component means the total content of the two or more types of substances.

In the present specification, a case in which at least one of screen printability, low resistance, and adhesion to a substrate is more superior may be referred to as “exhibiting a more superior effect of an embodiment of the present technology”.

### Electrically Conductive Composition

The electrically conductive composition of an embodiment of the present technology (composition of an embodiment of the present technology) is an electrically conductive composition containing:

electrically conductive particles;

an epoxy resin A that is a solid at 25° C. and has an epoxy equivalent weight of from 400 g/eq to less than 1500 g/eq, or an epoxy resin D that is a solid at 25° C. and has an epoxy equivalent weight of from 1500 g/eq to less than 3500 g/eq;

an epoxy resin B that is a liquid at 25° C. and has an epoxy equivalent weight of less than 400 g/eq;

a curing agent C; and

a solvent; wherein

a total amount 1 of the epoxy resin A, the epoxy resin B, and the curing agent C is from 3 parts by mass to 10 parts by mass per 100 parts by mass of the electrically conductive particles, or a total amount 2 of the epoxy resin D, the epoxy resin B, and the curing agent C is from 3 parts by mass to less than 6 parts by mass per 100 parts by mass of the electrically conductive particles;

a mass ratio [(A or D)/B] of the epoxy resin A or the epoxy resin D to the epoxy resin B is from 20/80 to 80/20; and

a mass ratio [C/{(A or D)+B}] of the curing agent C to a total amount of the epoxy resin A or the epoxy resin D and the epoxy resin B is from 2/98 to 10/90.

The composition according to an embodiment of the present technology is thought to achieve the desired effects as a result of having such a configuration. Although the reason for this is not clear, it is speculated that by using a solid epoxy resin A or D in combination with a liquid epoxy resin B, the epoxy resins having different epoxy equivalent weights, and setting, inter alia, the contents of each epoxy resin to a prescribed range, wire breakage or the like is unlikely to occur in screen printing, high aspect ratio wiring can be printed, the density of the electrically conductive particles can be increased, and the resulting cured product becomes tough, and therefore a balance among screen printability, low resistance, and adhesion to a substrate can be achieved at a high level.

Each of the components included in the composition according to an embodiment of the present technology will be described in detail below.

### Electrically Conductive Particles

The electrically conductive particles included in the composition according to an embodiment of the present technology are not particularly limited as long as they are a particulate shaped substance exhibiting electrical conductivity.

Examples of the electrically conductive particles include a metal material having electric resistivity of not greater than 20×10⁻⁶ Ω·cm.

Specific examples of the metal material include gold (Au), silver (Ag), copper (Cu), aluminum (Al), magnesium (Mg), and nickel (Ni).

From the perspective of achieving a more superior effect of an embodiment of the present technology, the electrically conductive particles are preferably at least one type selected from the group consisting of silver powder, copper powder, and silver coated electrically conductive powder coated with silver on at least a portion of the surface.

Examples of a core constituting the silver coated electrically conductive powder include particles of the metal material described above.

From the perspective of achieving a more superior effect of an embodiment of the present technology, the average particle diameter of the electrically conductive particles is preferably from 0.5 to 10 μm, and more preferably from 1 to 5 μm.

Here, in an embodiment of the present technology, the average particle diameter of the electrically conductive particles refers to an accumulated particle diameter at 50% (50% accumulated volume diameter; also referred to as the “average particle diameter (D50)”) that is determined by measuring the particle size distribution on a volume basis using a laser diffraction particle size distribution measurement device. An example of such a laser diffraction particle size distribution measurement device is a device that corresponds to the LA-500 (trade name) available from Horiba, Ltd.

From the perspective of achieving a more superior effect of an embodiment of the present technology, the electrically conductive particles preferably include at least one type selected from the group consisting of flake-shaped particles E and spherical particles F.

In an embodiment of the present technology, “spherical” refers to a shape of particles having a ratio of the major diameter to the minor diameter of 2 or less. Furthermore, “flake-shaped” refers to a shape in which the ratio of the major diameter to the minor diameter is greater than 2. Here, the major diameter and the minor diameter of the particles constituting the electrically conductive particles can be determined based on an image obtained from a scanning electron microscope (SEM). Also, “major diameter” refers to the longest line segment of the line segments passing through roughly the center of gravity of a particle in a particle image obtained by SEM. “Minor diameter” refers to the shortest line segment of the line segments passing through roughly the center of gravity of the particle in the particle image obtained by SEM.

The flake-shaped particles E may be either monocrystalline or polycrystalline.

From the perspective of achieving a more superior effect of an embodiment of the present technology, the specific surface area of the flake-shaped particles E is preferably from 0.2 to 1.0 m²/g, and more preferably from 0.2 to 0.8 m²/g. If the specific surface area is greater than 1.0 m²/g, the viscosity tends to increase, and a decrease in printability occurs. In order to obtain a composition with a viscosity range in which appropriate printing is possible, a larger amount of solvent must be blended in the composition, but this results in a decrease in the solid content, which in turn leads to a problem of a reduction in the aspect ratio of the wiring after printing and curing. If the specific surface area is less than 0.2 m²/g, the viscosity tends to decrease, and a reduction in printing properties such as a spread of the line width occurs. In order to obtain a composition with a viscosity range in which appropriate printing is possible, a smaller amount of solvent must be blended, but this makes viscosity control during manufacturing more difficult, and in turn, problems arise such as a tendency for the viscosity to vary due to drying of the solvent in a wiring step such as screen printing.

In an embodiment of the present technology, the specific surface area of the electrically conductive particles is a value determined based on the BET (Brauner Emmett Teller) equation from the adsorption isotherm of nitrogen at −196° C.

From the perspective of achieving a more superior effect of an embodiment of the present technology, the average particle diameter of the flake-shaped particles E is preferably from 1 to 15 μm, and more preferably from 3 to 10 μm. If the average particle diameter is greater than 10 μm, mesh clogging is easily caused in a wiring step such as screen printing, and problems arise in which wire breakage is prone to occur during fine line patterning. If the average particle diameter is less than 1 μm, the contact points between the electrically conductive particles increase, the contact resistance increases, and the resistance of the obtained wiring increases. Furthermore, due to the low thixotropy of the obtained composition, it becomes difficult to form high aspect ratio wiring in a wiring step such as screen printing.

From the perspective of achieving a more superior effect of an embodiment of the present technology, the specific surface area of the spherical particles F is preferably from 0.5 to 1.6 m²/g, and more preferably from 0.5 to 1.2 m²/g. If the specific surface area is greater than 1.6 m²/g, the viscosity tends to increase, and a decrease in printability occurs. In order to obtain a composition with a viscosity range in which appropriate printing is possible, a larger amount of solvent must be blended in the composition, but this results in a decrease in the solid content, which in turn leads to a problem of a reduction in the aspect ratio of the wiring after printing and curing. If the specific surface area is less than 0.5 m²/g, the viscosity tends to decrease, and a reduction in printing properties such as a spread of the line width occurs. In order to obtain a composition with a viscosity range in which appropriate printing is possible, a smaller amount of solvent must be blended, but this makes viscosity control during manufacturing more difficult, and in turn, problems arise such as a tendency for the viscosity to vary due to drying of the solvent in a wiring step such as screen printing.

From the perspective of achieving a more superior effect of an embodiment of the present technology and excelling in printability and electrical conductivity, the average particle diameter of the spherical particles F is preferably from 0.5 to 3 μm, and more preferably from 0.8 to 2 μm. If the average particle diameter is greater than 3 μm, the gap between the particles increases, and the density of the electrically conductive particles in the composition decreases, and therefore the resistance of the obtained wiring increases. If the average particle diameter is less than 0.5 μm, the contact points between the electrically conductive particles increase, the contact resistance increases, and the resistance of the obtained wiring increases.

In an embodiment of the present technology, when a plurality of types of electrically conductive particles are used as the electrically conductive particles, from the perspective of exhibiting a more superior effect of an embodiment of the present technology, the average specific surface area of the electrically conductive particles is preferably from 0.5 to 0.8 m²/g, and more preferably from 0.5 to 0.7 m²/g.

In an embodiment of the present technology, the average specific surface area of the electrically conductive particles can be obtained by dividing the sum of the product of the specific surface area of each conductive particle and its content by the sum of the content of each conductive particle.

When the above flake-shaped particles E and the spherical particles F are contained as electrically conductive particles, a mass ratio of the spherical particles F to the flake-shaped particles E ((spherical particles F)/(flake particles E)) is preferably from 75/25 to 25/75, and more preferably from 70/30 to 30/70 from the perspective of exhibiting a more superior effect of an embodiment of the present technology.

The method for producing the electrically conductive particles is not particularly limited. Examples thereof include conventionally known methods.

The method for producing the spherical electrically conductive particles (for example, the spherical particles F) is not particularly limited, and for example, spherical electrically conductive particles produced by a wet reduction method, an electrolytic method, an atomization method, or the like can be suitably used.

The method for producing flake-shaped electrically conductive particles (for example, the flake-shaped particles E) is not particularly limited, and a conventionally known method can be used. For example, flake-shaped electrically conductive particles produced by a method in which spherical electrically conductive particles produced by the method described above are used as an raw powder, the raw powder is then subjected to mechanical treatment using a ball mill, a bead mill, a vibration mill, a stirring type pulverizer, or the like, and the raw powder is formed into flakes by physical force can be suitably used.

### Epoxy Resins

The composition of an embodiment of the present technology contains a predetermined epoxy resin A or D and an epoxy resin B.

The epoxy resin A, B, or D contained in the composition of an embodiment of the present technology is a resin composed of a compound having two or more oxirane rings (epoxy groups) per molecule. The epoxy resin A, B, or D preferably has two or three oxirane rings per molecule.

### Epoxy Resin A

In an embodiment of the present technology, the epoxy resin A is an epoxy resin that is a solid at 25° C. and has an epoxy equivalent weight of from 400 g/eq to less than 1500 g/eq.

From the perspective of achieving a more superior effect of an embodiment of the present technology, the epoxy equivalent weight of the epoxy resin A is preferably from 400 to 1000 g/eq.

From the perspective of achieving a more superior effect of an embodiment of the present technology, the softening point of the epoxy resin A is preferably less than 115° C., and more preferably from 60 to 105° C.

In an embodiment of the present technology, the softening point of the epoxy resin was measured in accordance with JIS K-7234.

Examples of the epoxy resin A include epoxy resins of bisphenol skeletons such as bisphenol A, bisphenol F, bisphenol E, brominated bisphenol A, hydrogenated bisphenol A, bisphenol S, and bisphenol AF type epoxy resins.

Among these, from the perspective of achieving a more superior effect of an embodiment of the present technology, the epoxy resin A is, for example, preferably at least one type selected from the group consisting of bisphenol A and bisphenol F type epoxy resins. The bisphenol A type and the bisphenol F type epoxy resins may be used in combination as the epoxy resin A.

Additionally, the epoxy resin A preferably contains a bisphenol F type epoxy resin from the perspective of better excelling in screen printability (particularly 60 μm printability) because the viscosity of the composition can be set to an appropriate range.

The viscosity of the epoxy resin A is preferably from A to U, more preferably from L to U, and even more preferably from 0 to U from the perspective of better excelling in screen printability (particularly 60 μm printability) and enabling the viscosity of the composition to be in an appropriate range.

In an embodiment of the present technology, the viscosity of the epoxy resin A can be evaluated, for example, by performing a viscosity test through the Gardner-Holdt method using a butyl carbitol 40% (solid content) solution at 25° C.

### Epoxy Resin D

In an embodiment of the present technology, the epoxy resin D is an epoxy resin that is a solid at 25° C. and has an epoxy equivalent weight of from 1500 g/eq to less than 3500 g/eq.

From the perspective of achieving a more superior effect of an embodiment of the present technology, the epoxy equivalent weight of the epoxy resin D is preferably from 1500 to 2500 g/eq.

From the perspective of achieving a more superior effect of an embodiment of the present technology, the softening point of the epoxy resin D is preferably from 115° C. to 150° C., and more preferably from 115 to 135° C.

Examples of the epoxy resin D include epoxy resins of bisphenol skeletons such as bisphenol A, bisphenol F, bisphenol E, brominated bisphenol A, hydrogenated bisphenol A, bisphenol S, and bisphenol AF type epoxy resins.

Among these, from the perspective of achieving a more superior effect of an embodiment of the present technology, the epoxy resin D is preferably at least one type selected from the group consisting of bisphenol A and bisphenol F type epoxy resins. The bisphenol A type and the bisphenol F type epoxy resins may be used in combination as the epoxy resin D.

Additionally, the epoxy resin D preferably contains a bisphenol F type epoxy resin from the perspective of better excelling in screen printability (particularly 60 μm printability) because the viscosity of the epoxy resin D is low, and the viscosity of the composition can be reduced.

The viscosity of the epoxy resin D is preferably from V to Zs, and more preferably from V to Z₂ from the perspective of better excelling in screen printability (particularly 60 μm printability) and enabling the viscosity of the composition to be reduced. When a bisphenol F type epoxy resin is used as the epoxy resin D, the viscosity of the bisphenol F type epoxy resin is preferably from X to Z₂ from the perspective better excelling in screen printability (particularly 60 μm printability) because the viscosity of the epoxy resin D is low, and the viscosity of the composition can be reduced.

In an embodiment of the present technology, the viscosity of the epoxy resin D can be evaluated, for example, by performing a viscosity test through the Gardner-Holdt method using a butyl carbitol 40% (solid content) solution at 25° C.

### Epoxy Resin B

In an embodiment of the present technology, the epoxy resin B is an epoxy resin that is a liquid at 25° C. and has an epoxy equivalent weight of less than 400 g/eq.

From the perspective of achieving a more superior effect of an embodiment of the present technology, the epoxy equivalent weight of the epoxy resin B is preferably from 100 g/eq to less than 400 g/eq, and more preferably from 150 to 300 g/eq.

From the perspective of achieving a more superior effect (particularly a low resistance) of an embodiment of the present technology, the epoxy equivalent weight of the epoxy resin B is preferably from 200 g/eq to less than 400 g/eq, more preferably from 250 to 390 g/eq, even more preferably from 300 to 380 g/eq, and particularly preferably greater than 300 g/eq but not greater than 380 g/eq.

From the perspective of achieving a more superior effect of an embodiment of the present technology, the viscosity of the epoxy resin B at 25° C. is preferably from 15 to 5000 mPa·s, and more preferably from 30 to 1000 mPa·s.

In an embodiment of the present technology, the viscosity of the epoxy resins were measured in accordance with JIS Z 8803 at 25° C.

Examples of the epoxy resin B include epoxy resins having a bisphenol skeleton such as bisphenol A type, bisphenol F type, bisphenol E type, brominated bisphenol A type, hydrogenated bisphenol A type, bisphenol S type, and bisphenol AF type;

epoxy resins having a biphenyl skeleton;

polyhydric alcohol glycidyl-type epoxy resins such as glycidyl ethers of poly(oxyalkylene) polyols and glycidyl ethers of alkylene polyols;

chelate-modified epoxy resins;

epoxy resins having a benzenediol (dihydroxybenzene) skeleton and hydrogenated products thereof;

epoxy resins having a phthalic acid skeleton and hydrogenated products thereof;

epoxy resins having a benzenedimethanol skeleton;

epoxy resins having a cyclohexane dimethanol skeleton;

epoxy resins having a dicyclopentadiene dimethanol skeleton;

epoxy resins having an aniline skeleton; and

epoxy resins having a toluidine skeleton.

A single epoxy resin B can be used, or two or more epoxy resins B can be used in combination.

Among these, from the perspective of achieving a more superior effect of an embodiment of the present technology, the epoxy resin B is preferably at least one type selected from the group consisting of epoxy resins having a bisphenol skeleton, and polyhydric alcohol glycidyl-type epoxy resins;

more preferably at least one type selected from the group consisting of bisphenol A type, bisphenol F type, brominated bisphenol A type, hydrogenated bisphenol A type, bisphenol S type, bisphenol AF type, and polyhydric alcohol glycidyl-type epoxy resins;

even more preferably a polyhydric alcohol glycidyl-type epoxy resin;

and particularly preferably a poly(oxyalkylene) polyol glycidyl-type epoxy resin.

The poly(oxyalkylene) polyol or alkylene polyol that can constitute the polyhydric alcohol glycidyl-type epoxy resin is not particularly limited.

The alkylene group contained in the poly(oxyalkylene) polyol or alkylene polyol may be linear, branched, cyclic, or a combination thereof. The number of carbon atoms in the alkylene group can be, for example, from 2 to 15.

Examples of the alkylene group include an ethylene group, a propylene group, and a trimethylene group. Among these, from the perspective of obtaining a more superior effect of an embodiment of the present technology, an ethylene group is preferable.

From the perspective of obtaining a more superior effect of an embodiment of the present technology, the number of repeating units (oxyalkylene groups) contained in the poly(oxyalkylene) polyol is preferably from 2 to 10.

From the perspective of obtaining a more superior effect (particularly a low resistance) of an embodiment of the present technology, the number of repeating units (oxyalkylene groups) contained in the poly(oxyalkylene) polyol is preferably from 10 to 15.

Examples of the glycidyl ether of the alkylene polyol include ethylene glycol diglycidyl ether and propylene glycol diglycidyl ether.

Examples of commercially available products of the glycidyl ether of the alkylene polyol include product under the trade name EX-810 (available from Nagase Chemtex Corporation).

Examples of the glycidyl ether of the poly(oxyalkylene) polyol include polyethylene glycol diglycidyl ether and polypropylene glycol diglycidyl ether.

Examples of commercially available products of the glycidyl ether of the poly(oxyalkylene) polyol include products under the trade names EX-830, EX-841, and EX-920 (available from Nagase Chemtex Corporation).

### (A or D)/B

In an embodiment of the present technology, the mass ratio of [(A or D)/B] of the epoxy resin A or the epoxy resin D to the epoxy resin B is from 20/80 to 80/20.

From the perspective of achieving a more superior effect of an embodiment of the present technology, [(A or D)/B] is preferably from 25/75 to 75/25, and more preferably from 40/60 to 60/40.

The method for producing the epoxy resin A is not particularly limited. Examples thereof include conventionally known methods. The same applies to the epoxy resin D and the epoxy resin B.

### Curing Agent C

The curing agent C included in the composition of an embodiment of the present technology is not particularly limited, provided that it can be used as a curing agent for epoxy resins. Of these, cationic curing agents are preferable. Examples of cationic curing agents include amine-based, sulfonium-based, ammonium-based, and phosphonium-based curing agents.

Examples of the curing agent C include: a complex of boron trifluoride and an amine compound such as boron trifluoride-ethylamine, boron trifluoride-piperidine, and boron trifluoride-triethanolamine;

boron trifluoride-phenol;

p-methoxybenzenediazonium hexafluorophosphate, and diphenyliodonium hexafluorophosphate;

sulfonium-based curing agents such as tetraphenylsulfonium;

and phosphonium-based curing agents such as tetra-n-butylphosphonium tetraphenylborate, and tetra-n-butylphosphonium-o,o-diethylphosphorodithioate.

Among these, from the perspective of being capable of further reducing the volume resistivity, a complex of boron trifluoride and an amine compound is preferable, and use of at least one type of complex that is a complex of boron trifluoride and an amine compound and is selected from the group consisting of boron trifluoride-ethylamine, boron trifluoride-piperidine, and boron trifluoride-triethanolamine is more preferable.

The method for producing the curing agent is not particularly limited. Examples thereof include conventionally known methods.

### Total Amount 1

When the composition according to an embodiment of the present technology contains the epoxy resin A, the total amount 1 of the epoxy resin A, the epoxy resin B, and the curing agent C is from 3 parts by mass to 10 parts by mass per 100 parts by mass of the electrically conductive particles.

From the perspective of achieving a more superior effect of an embodiment of the present technology, the total amount 1 is preferably from 3 to 8 parts by mass, more preferably from 5 to 8 parts by mass, and even more preferably from 5 to 7.0 parts by mass per 100 parts by mass of the electrically conductive particles.

### Total Amount 2

When the composition according to an embodiment of the present technology contains the epoxy resin D, the total amount 2 of the epoxy resin D, the epoxy resin B, and the curing agent C is from 3 parts by mass to less than 6 parts by mass per 100 parts by mass of the electrically conductive particles.

From the perspective of achieving a more superior effect of an embodiment of the present technology, the total amount 2 is preferably from 3 to 5 parts by mass per 100 parts by mass of the electrically conductive particles.

From the perspective of achieving a more superior effect (particularly screen printability and/or low resistance) of an embodiment of the present technology, the total amount 2 is preferably from 5.0 to 5.4 parts by mass per 100 parts by mass of the electrically conductive particles.

In addition, from the perspective of achieving a more superior effect (particularly screen printability and/or low resistance) of an embodiment of the present technology, when the epoxy resin B is only a polyhydric alcohol glycidyl-type epoxy resin, the total amount 2 is preferably from 4.0 to 5.4 parts by mass, and more preferably from 4.5 to 5.4 parts by mass per 100 parts by mass of the electrically conductive particles.

C/{(A or D)+B}

In an embodiment of the present technology, the mass ratio [C/{(A or D)+B}] of the curing agent C to the total amount of the epoxy resin A or the epoxy resin D and the epoxy resin B is from 2/98 to 10/90.

From the perspective of achieving a more superior effect of an embodiment of the present technology, [C/{(A or D)+B}] is preferably from 3/97 to 10/90, and more preferably from 3/97 to 8/92.

### Solvent

The composition of an embodiment of the present technology contains a solvent.

The solvent is not particularly limited. Examples thereof include butyl carbitol, butyl carbitol acetate, cyclohexanone, methyl ethyl ketone, isophorone, and α-terpineol.

A commercially available product can be used as the solvent.

From the perspective of achieving a more superior effect of an embodiment of the present technology, the content of the solvent is preferably from 20 to 200 parts by mass, and more preferably from 40 to 100 parts by mass per 100 parts by mass of the epoxy resin A or D, the epoxy resin B, and the curing agent C.

### Additives

The composition according to an embodiment of the present technology may further contain, as necessary, additives such as epoxy resins other than the above epoxy resins A, B, and D, reducing agents, and fatty acid metal salts.

Specific examples of the reducing agents include ethylene glycols.

The fatty acid metal salt is not particularly limited as long as it is a metal salt of an organic carboxylic acid, and for example, use of a carboxylic acid salt of one or more types of metals selected from a group consisting of silver, magnesium, nickel, copper, zinc, yttrium, zirconium, tin, and lead is preferable. Of these, the use of a carboxylic acid salt of silver (hereinafter, also referred to as a “silver carboxylate”) is preferable.

Here, the silver carboxylate is not particularly limited as long as it is a silver salt of an organic carboxylic acid (fatty acid), and examples thereof that can be used include the fatty acid metal salts (particularly, the tertiary fatty acid silver salts) described in paragraphs [0063] to [0068] of JP 2008-198595 A, and the fatty acid silver salt described in paragraph [0030] of JP 4482930 B, the fatty acid silver salt having one or more of hydroxyl groups described in paragraphs [0029] to [0045] and the secondary fatty acid silver salt described in paragraphs [0046] to [0056] of JP 2010-92684 A, and the silver carboxylate described in paragraphs [0022] to [0026] of JP 2011-35062 A.

In the composition of an embodiment of the present technology, glass frit that is commonly used as a high temperature (700 to 800° C.) sintering type electrically conductive paste is not particularly required. An example of a preferable aspect is one in which the composition according to an embodiment of the present technology substantially does not contain glass frit (the content of glass frit is from 0 to 0.1 parts by mass per 100 parts by mass of the electrically conductive particles).

### Method of Producing the Electrically Conductive Composition

The method of producing the composition according to an embodiment of the present technology is not particularly limited, and examples thereof include a method of mixing the components described above using, for example, a roll, kneader, extruder, or universal mixer.

The composition according to an embodiment of the present technology can be cured by, for example, applying the composition of an embodiment of the present technology to a substrate and heating at 180 to 230° C.

The substrate is not particularly limited. Examples thereof include silicon substrates, glass, metal, resin substrates, and films. The substrate may be subjected to, for example, a treatment of TCO (transparent conductive oxide film) such as ITO (indium tin oxide).

The cured product formed using the composition according to an embodiment of the present technology can be used, for example, as an electrode (collecting electrode) of a solar cell, an electrode of a touch panel, and a die bond of an LED (light emitting diode).

Solar cell modules can be manufactured using solar cells having electrodes formed using a composition of an embodiment of the present technology.

### Examples

The present technology is described below in detail using examples. However, the present technology is not limited to such examples.

### Composition Production

The components listed in Table 1 below were used at the amounts (parts by mass) listed in the same table, and were mixed by an agitator to produce respective compositions.

### Evaluation

The following evaluations were performed using the compositions produced as described above. The results are shown in Table 1.

### Volume Resistivity (Specific Resistance)

Each composition produced as described above was applied onto a glass substrate by screen printing to form a 2 cm×2 cm test pattern of a solid coating. Subsequently, the coating was dried and cured in an oven at 200° C. for 30 minutes to produce an electrically conductive coating film.

For each of the fabricated electrically conductive coating films, the volume resistivity was evaluated by a 4-terminal 4-probe method using a resistivity meter (Loresta-GP, available from Mitsubishi Chemical Corporation).

The volume resistivity was determined to be good when less than 8.0 μΩ·cm.

### Screen Printability

The 60 μm printability and aspect ratio were evaluated for screen printability.

Through the following evaluations, embodiments of the present technology were considered to excel in screen printability when the 60 μm printability was good (∘) or excellent (⊚), and the aspect ratio was good (∘) or excellent (⊚).

60 μm Printability

A screen printing plate A with a line opening width of 60 μm was fabricated using a stainless steel screen mask with a mesh count of 360 mesh, an emulsion thickness of 25 μm, a wiring opening width of 60 μm, a wire diameter of 16 μm, and an opening of 55 μm.

Next, each composition produced as described above was screen printed at a printing speed of 200 mm/second using the screen printing plate A, and wiring with a line width of from 60 to 80 μm was obtained.

As described above, the wiring obtained by screen printing was observed using a laser microscope (magnification factor of 300 times), and the acceptability of printability with an opening width of 60 μm was determined according to the following criteria.

When there was no confirmation of any wire breakage, meandering, oozing, or mesh traces, the printability with an opening width of 60 μm was evaluated as being excellent, and indicated by “⊚”. When wire breakage was not confirmed, but one of any of meandering, oozing, and mesh traces was confirmed, the printability with an opening width of 60 μm was evaluated as being good, and indicated by “∘”. When wire breakage was not confirmed, but two or more of any of meandering, oozing, and mesh traces were confirmed, the printability with an opening width of 60 μm was evaluated as being inferior, and indicated by “Δ”. When wire breakage was confirmed, the printability with an opening width of 60 μm was evaluated as being extremely inferior, and indicated by “x”.

Aspect Ratio

As described above, the wiring obtained by screen printing was observed using a laser microscope (magnification factor of 300 times), the width and height of the wiring were measured, and the ratio (height/width) was measured as an aspect ratio.

Cases in which the aspect ratio was 0.3 or greater were evaluated as “⊚”. Cases in which the aspect ratio was from 0.25 to less than 0.3 were evaluated as “∘”. Cases in which the aspect ratio was from 0.2 to less than 0.25 were evaluated as “Δ”, and cases in which the aspect ratio was less than 0.2 were evaluated as “x”.

### Adhesiveness

A film of ITO (Sn doped indium oxide) was formed as a transparent conductive layer on the surface of a silicon substrate.

Next, each composition produced as described above was applied onto the transparent conductive layer by screen printing at a printing speed of 200 mm/second to form a thin line shaped test pattern having a width of from 60 to 80 μm and a length of 25 mm. The screen printing mask used at this time had a mesh of 360, an emulsion thickness of 25 μm, a wiring opening width of 60 μm, a wire diameter of 16 μm, and an opening of 55 μm.

Subsequently, the test pattern was dried and cured for 30 minutes at 200° C., and a test sample having 20 wires on the transparent conductive layer was fabricated.

Next, a peel test was performed in which one tape was affixed in a direction perpendicular to all of the wires, and the tape was immediately peeled from the test sample.

Following the peeling test, cases in which the wiring did not peel at all were evaluated as excelling in adhesiveness, and indicated by “∘”.

Cases in which one or two of the 20 wires peeled were evaluated as having somewhat inferior adhesiveness, and indicated by “Δ”.

Cases in which three or more of the 20 wires peeled were evaluated as having very inferior adhesiveness, and indicated by “x”.

TABLE 1

| | | | | | | | Comparative | |
|---|---|---|---|---|---|---|---|---|
| | | Example 1 | Example 2 | Example 3 | Example 4 | Example 5 | Example 1 | Example 6 |
| Flake Silver | E-1 | | | | | | | |
| | E-2 | 45.75 | 45.66 | 45.58 | 45.79 | 45.33 | 45.54 | 45.66 |
| | E-3 | | | | | | | |
| Spherical | F-1 | | | | | | | |
| Silver | F-2 | 45.75 | 45.66 | 45.58 | 45.79 | 45.33 | 45.54 | 45.66 |
| | F-3 | | | | | | | |
| Epoxy Resin | A-1 | | | | | | | |
| A/D | A-2 | | | | | | | 2.74 |
| | A-3 | 2.74 | 2.74 | 2.73 | 2.75 | 2.72 | 2.73 | |
| | A-4 | | | | | | | |
| | D-1 | | | | | | | |
| | D-2 | | | | | | | |
| | D-3 | | | | | | | |
| | A-5 | | | | | | | |
| Epoxy Resin B | B-1 | 2.74 | | | | | | |
| | B-2 | | 2.74 | | | | | |
| | B-3 | | | 2.73 | | | | 2.74 |
| | B-4 | | | | 2.75 | | | |
| | B-5 | | | | | 2.72 | | |
| | B-6 | | | | | | 2.73 | |
| Curing Agent C | C-1 | 0.27 | 0.27 | 0.27 | 0.27 | 0.27 | 0.27 | 0.27 |
| Solvent | | 2.75 | 2.93 | 3.11 | 2.65 | 3.63 | 3.19 | 2.93 |
| Total | | 100.00 | 100.00 | 100.00 | 100.00 | 100.00 | 100.00 | 100.00 |
| Volume | μΩ · cm | 6.8 | 6.5 | 6.4 | 7.5 | 7.6 | 8.5 | 6.6 |
| Resistivity | | | | | | | | |
| Screen | 60 μm | ⊚ | ⊚ | ⊚ | ⊚ | ◯ | Δ | ⊚ |
| Printability | Printability | | | | | | | |
| | Aspect | ⊚ | ⊚ | ⊚ | ⊚ | ⊚ | ◯ | ⊚ |
| | Ratio | | | | | | | |

| | | | | | | | |
|---|---|---|---|---|---|---|---|
| Adhesiveness | ◯ | ◯ | ◯ | ◯ | ◯ | ◯ | ◯ |

| | | | | | Example | Comparative | Comparative |
|---|---|---|---|---|---|---|---|
| | | Example 7 | Example 8 | Example 9 | 10 | Example 2 | Example 3 |
| Flake Silver | E-1 | | | | | | |
| | E-2 | 45.91 | 45.98 | 45.85 | 46.19 | 45.83 | 45.91 |
| | E-3 | | | | | | |
| Spherical Silver | F-1 | | | | | | |
| | F-2 | 45.91 | 45.98 | 45.85 | 46.19 | 45.83 | 45.91 |
| | F-3 | | | | | | |
| Epoxy Resin A/D | A-1 | | | | | 2.75 | |
| | A-2 | | | | | | |
| | A-3 | | | | | | |
| | A-4 | 2.75 | | | | | |
| | D-1 | | 2.30 | | | | |
| | D-2 | | | 2.29 | | | |
| | D-3 | | | | 2.31 | | |
| | A-5 | | | | | | 2.75 |
| Epoxy Resin B | B-1 | | | | | | |
| | B-2 | | | | | | |
| | B-3 | 2.75 | 2.30 | 2.29 | 2.31 | 2.75 | 2.75 |
| | B-4 | | | | | | |
| | B-5 | | | | | | |
| | B-6 | | | | | | |
| Curing Agent C | C-1 | 0.28 | 0.23 | 0.23 | 0.23 | 0.27 | 0.28 |
| Solvent | | 2.40 | 3.21 | 3.49 | 2.77 | 2.57 | 2.40 |
| Total | | 100.00 | 100.00 | 100.00 | 100.00 | 100.00 | 100.00 |
| Volume | μΩ · cm | 7.8 | 6.5 | 6.4 | 7.2 | 7.0 | 11.3 |
| Resistivity | | | | | | | |
| Screen Printability | 60 μm | ⊚ | ◯ | ◯ | ⊚ | Δ | ◯ |
| | Printability | | | | | | |
| | Aspect | ⊚ | ◯ | ◯ | ◯ | ⊚ | ◯ |
| | Ratio | | | | | | |

| | | | | | | |
|---|---|---|---|---|---|---|
| Adhesiveness | ◯ | ◯ | ◯ | ◯ | ◯ | Δ |

| | | Example | Comparative | Comparative | Comparative | Example | Comparative |
|---|---|---|---|---|---|---|---|
| | | 11 | Example 4 | Example 5 | Example 6 | 12 | Example 7 |
| Flake | E-1 | | | | | | |
| Silver | E-2 | 44.09 | 42.92 | 45.48 | 45.43 | 46.23 | 46.25 |
| | E-3 | | | | | | |
| Spherical | F-1 | | | | | | |
| Silver | F-2 | 44.09 | 42.92 | 45.48 | 45.43 | 46.23 | 46.25 |
| | F-3 | | | | | | |
| Epoxy | A-1 | | | | | | |
| Resin A/D | A-2 | | | | | | |
| | A-3 | 3.53 | 4.29 | | | 1.39 | 0.93 |
| | A-4 | | | | | | |
| | D-1 | | | 2.73 | | | |
| | D-2 | | | | 2.73 | | |
| | D-3 | | | | | | |
| | A-5 | | | | | | |
| Epoxy | B-1 | | | | | | |
| Resin B | B-2 | 3.53 | 4.29 | | | 1.39 | 0.93 |
| | B-3 | | | 2.73 | 2.73 | | |
| | B-4 | | | | | | |
| | B-5 | | | | | | |
| | B-6 | | | | | | |
| Curing | C-1 | 0.35 | 0.43 | 0.23 | 0.23 | 0.14 | 0.09 |
| Agent C | | | | | | | |
| Solvent | | 4.41 | 5.15 | 3.35 | 3.45 | 4.62 | 5.55 |
| Total | | 100.00 | 100.00 | 100.00 | 100.00 | 100.00 | 100.00 |
| Volume | μΩ · cm | 7.5 | 8.6 | 7.2 | 7.0 | 6.0 | 5.5 |
| Resistivity | | | | | | | |
| Screen | 60 μm | ◯ | Δ | Δ | Δ | ◯ | X |
| Printability | Printability | | | | | | |
| | Aspect | ◯ | Δ | Δ | Δ | ⊚ | ⊚ |
| | Ratio | | | | | | |

| | | | | | | |
|---|---|---|---|---|---|---|
| Adhesiveness | ◯ | ◯ | ◯ | ◯ | ◯ | X |

| | | Example | Example | Comparative | Example | Example | Comparative |
|---|---|---|---|---|---|---|---|
| | | 13 | 14 | Example 8 | 15 | 16 | Example 9 |
| Flake Silver | E-1 | | | | | | |
| | E-2 | 45.62 | 45.81 | 45.83 | 45.54 | 45.96 | 45.54 |
| | E-3 | | | | | | |
| Spherical | F-1 | | | | | | |
| Silver | F-2 | 45.62 | 45.81 | 45.83 | 45.54 | 45.96 | 45.54 |
| | F-3 | | | | | | |
| Epoxy Resin | A-1 | | | | | | |
| A/D | A-2 | | | | | | |
| | A-3 | 2.74 | 2.75 | 2.75 | 4.10 | 1.38 | 4.55 |
| | A-4 | | | | | | |
| | D-1 | | | | | | |
| | D-2 | | | | | | |
| | D-3 | | | | | | |
| | A-5 | | | | | | |
| Epoxy Resin B | B-1 | | | | | | |
| | B-2 | 2.74 | 2.75 | 2.75 | 1.37 | 4.14 | 0.91 |
| | B-3 | | | | | | |
| | B-4 | | | | | | |
| | B-5 | | | | | | |
| | B-6 | | | | | | |
| Curing Agent C | C-1 | 0.55 | 0.14 | 0.09 | 0.27 | 0.28 | 0.27 |
| Solvent | | 2.73 | 2.74 | 2.75 | 3.18 | 2.28 | 3.19 |
| Total | | 100.00 | 100.00 | 100.00 | 100.00 | 100.00 | 100.00 |
| Volume | μΩ · cm | 6.3 | 7.6 | 8.5 | 6.3 | 6.8 | 6.0 |
| Resistivity | | | | | | | |
| Screen | 60 μm | ⊚ | ⊚ | ⊚ | ◯ | ◯ | Δ |
| Printability | Printability | | | | | | |
| | Aspect | ⊚ | ⊚ | ⊚ | ◯ | ◯ | Δ |
| | Ratio | | | | | | |
| Adhesiveness | | ◯ | ◯ | Δ | ◯ | ◯ | ◯ |
| | | Comparative | Example | Example | Example | Example | Example |
| | | Example 10 | 17 | 18 | 19 | 20 | 21 |
| Flake Silver | E-1 | | 46.10 | 64.55 | 27.66 | 46.10 | |
| | E-2 | 45.96 | | | | | 46.10 |
| | E-3 | | | | | | |
| Spherical Silver | F-1 | | 46.10 | 27.66 | 64.55 | | 46.10 |
| | F-2 | 45.96 | | | | 46.10 | |
| | F-3 | | | | | | |
| Epoxy Resin | A-1 | | | | | | |
| A/D | A-2 | | | | | | |
| | A-3 | 0.92 | | | | | |
| | A-4 | | | | | | |
| | D-1 | | 2.31 | 2.31 | 2.31 | 2.31 | 2.31 |
| | D-2 | | | | | | |
| | D-3 | | | | | | |
| | A-5 | | | | | | |
| Epoxy Resin B | B-1 | | | | | | |
| | B-2 | 4.60 | | | | | |
| | B-3 | | 2.31 | 2.31 | 2.31 | 2.31 | 2.31 |
| | B-4 | | | | | | |
| | B-5 | | | | | | |
| | B-6 | | | | | | |
| Curing Agent C | C-1 | 0.28 | 0.23 | 0.23 | 0.23 | 0.23 | 0.23 |
| Solvent | | 2.28 | 2.95 | 2.94 | 2.94 | 2.95 | 2.95 |
| Total | | 100.00 | 100.00 | 100.00 | 100.00 | 100.00 | 100.00 |
| Volume | μΩ · cm | 7.2 | 5.8 | 5.2 | 7.0 | 6.4 | 7.2 |
| Resistivity | | | | | | | |
| Screen | 60 μm | Δ | ⊚ | ◯ | ⊚ | ⊚ | ◯ |
| Printability | Printability | | | | | | |
| | Aspect | ⊚ | ⊚ | ⊚ | ⊚ | ⊚ | ⊚ |
| | Ratio | | | | | | |

| | | | | | | |
|---|---|---|---|---|---|---|
| Adhesiveness | ◯ | ◯ | ◯ | ◯ | ◯ | ◯ |

| | | Example | Example | Example | Example | Example | Example | Example |
|---|---|---|---|---|---|---|---|---|
| | | 22 | 23 | 24 | 25 | 26 | 27 | 28 |
| Flake Silver | E-1 | | | | | | | |
| | E-2 | 46.10 | | | | | 46.39 | 46.14 |
| | E-3 | | 46.10 | 46.10 | 46.10 | 36.88 | | |
| Spherical | F-1 | | 46.10 | | | | | |
| Silver | F-2 | | | 46.10 | | | 46.39 | 46.14 |
| | F-3 | 46.10 | | | 46.10 | 55.33 | | |
| Epoxy Resin | A-1 | | | | | | | |
| A/D | A-2 | | | | | | | |
| | A-3 | | | | | | | |
| | A-4 | | | | | | | |
| | D-1 | 2.31 | 2.31 | 2.31 | 2.31 | 2.31 | | |
| | D-2 | | | | | | | |
| | D-3 | | | | | | 1.67 | 2.49 |
| | A-5 | | | | | | | |
| Epoxy Resin B | B-1 | | | | | | | |
| | B-2 | | | | | | | |
| | B-3 | 2.31 | 2.31 | 2.31 | 2.31 | 2.31 | 1.67 | 2.49 |
| | B-4 | | | | | | | |
| | B-5 | | | | | | | |
| | B-6 | | | | | | | |
| Curing Agent C | C-1 | 0.23 | 0.23 | 0.23 | 0.23 | 0.23 | 0.17 | 0.25 |
| Solvent | | 2.95 | 2.95 | 2.95 | 2.95 | 2.94 | 3.71 | 2.49 |
| Total | | 100.00 | 100.00 | 100.00 | 100.00 | 100.00 | 100.00 | 100.00 |
| Volume | μΩ · cm | 6.8 | 7.5 | 7.2 | 7.0 | 7.2 | 6.5 | 7.5 |
| Resistivity | | | | | | | | |
| Screen | 60 μm | ⊚ | ◯ | ◯ | ◯ | ⊚ | ◯ | ◯ |
| Printability | Printability | | | | | | | |
| | Aspect | ⊚ | ⊚ | ⊚ | ⊚ | ⊚ | ◯ | ◯ |
| | Ratio | | | | | | | |

| | | | | | | | |
|---|---|---|---|---|---|---|---|
| Adhesiveness | ◯ | ◯ | ◯ | ◯ | ◯ | ◯ | ◯ |

Details of the components listed in Table 1 are as follows.

TABLE 2

| Flake | E-1 | 0.26 m²/g (Specific Surface Area) | |
|---|---|---|---|
| Silver | E-2 | 0.67 m²/g (Specific Surface Area) | |
| | E-3 | 1.23 m²/g (Specific Surface Area) | |
| Spherical | F-1 | 1.09 m²/g (Specific Surface Area) | |
| Silver | F-2 | 0.64 m²/g (Specific Surface Area) | |
| | F-3 | 0.40 m²/g (Specific Surface Area) | |
| Epoxy | A-1 | YD-134: 230 to 270 g/eq | Available from |
| Resin A/D | | | Nippon Steel & |
| | | | Sumikin Chemical |
| | | | Co., Ltd.: Bis A: |
| | | | solid |
| | A-2 | 1055: 450 to 500 g/eq | DIC: Bis A: solid |
| | | | (softening point: |
| | | | 62 to 73° C.) |
| | A-3 | 4050: 900 to 1000 g/eq | DIC: Bis A: solid |
| | | | (softening point: |
| | | | 96 to 104° C.) |
| | A-4 | jER4005P: 950 to 1200 g/eq | Mitsubishi |
| | | | Chemical: Bis F: |
| | | | solid (softening |
| | | | point: 87° C.) |
| | D-1 | 7050: 1750 to 2100 g/eq | DIC: Bis A: solid |
| | | | (softening point: |
| | | | 122 to 131° C.) |
| | D-2 | jER1009: 2400 to 3300 g/eq | Mitsubishi |
| | | | Chemical: Bis A: |
| | | | solid (softening |
| | | | point: 144° C.) |
| | D-3 | jER4007P: 2000 to 2500 g/eq | Mitsubishi |
| | | | Chemical: Bis F: |
| | | | solid (softening |
| | | | point: 108° C.) |
| | A-5 | NC-3000: 265 to 285 g/eq | Nippon Kayaku: |
| | | | Biphenyl Type: |
| | | | solid (softening |
| | | | point: 53 to |
| | | | 63° C.) |
| Epoxy | B-1 | EX-810: 113 g/eq | Nagase Chemtex: |
| Resin B | | | polyhydric alcohol- |
| | | | based glycidyl type: |
| | | | liquid (viscosity: |
| | | | 20 mPa · s) |
| | B-2 | EX-830: 268 g/eq | Nagase Chemtex: |
| | | | polyhydric alcohol- |
| | | | based glycidyl type: |
| | | | liquid (viscosity: |
| | | | 70 mPa · s) |
| | B-3 | EX-841: 372 g/eq | Nagase Chemtex: |
| | | | polyhydric alcohol- |
| | | | based glycidyl type: |
| | | | liquid (viscosity: |
| | | | 110 mPa · s) |
| | B-4 | EX-920: 176 g/eq | Nagase Chemtex: |
| | | | polyhydric alcohol- |
| | | | based glycidyl type: |
| | | | liquid (viscosity: |
| | | | 20 mPa · s) |
| | B-5 | jER806: 160 to 170 g/eq | Mitsubishi |
| | | | Chemical: Bis F: |
| | | | liquid (1500 to |
| | | | 2500 mPa · s) |
| | B-6 | EX-931: 471 g/eq | Nagase Chemtex: |
| | | | polyhydric alcohol- |
| | | | based glycidyl type: |
| | | | liquid (120 mPa · s) |
| Curing | C-1 | Boron trifluoride | Available from |
| Agent C | | monoethylamine | Stella Chemifa |
| Solvent | | Butyl carbitol | Available from |
| | | | Sankyo Chemical |

Furthermore, the viscosity (Gardner-Holdt method above) of the epoxy resin A-4 is from O to U.

The viscosity (Gardner-Holdt method above) of the epoxy resin D-3 is from X to Z₂.

Note that in Table 1 and Table 2, the flake-shaped silvers E-1 to E-3 correspond to the flake-shaped particles E of the electrically conductive particles of an embodiment of the present technology.

Additionally, the spherical silvers F-1 to F-3 correspond to the spherical particles F of the electrically conductive particles of an embodiment of the present technology.

The epoxy resins A-2 to A-4 in the Epoxy Resin A/D section correspond to the epoxy resin A in an embodiment of the present technology.

Furthermore, the epoxy resins D-1 to D-3 in the Epoxy Resin A/D section correspond to the epoxy resin D in an embodiment of the present technology.

The epoxy resins B-1 to B-5 of the Epoxy Resin B section correspond to the epoxy resin B in an embodiment of the present technology.

As is clear from the results shown in Table 1, Comparative Example 1, which contained the epoxy resin B-6 (liquid at 25° C., but with an epoxy equivalent weight that exceeded 400 g/eq) instead of the prescribed epoxy resin B, exhibited high resistance and poor screen printability.

Comparative Example 2, which contained the epoxy resin A-1 (solid at 25° C., but with an epoxy equivalent weight of less than 400 g/eq) instead of the prescribed epoxy resin A, exhibited poor screen printability.

Comparative Example 3, which contained the epoxy resin A-5 (solid at 25° C., but with an epoxy weight equivalent of less than 400 g/eq) instead of the prescribed epoxy resin A, exhibited high resistance and poor adhesiveness.

Comparative Example 4, in which the total amount 1 of the epoxy resin A, the epoxy resin B, and the curing agent C was outside the predetermined range, exhibited high resistance and poor screen printability.

Comparative Examples 5 to 6, in which the total amount 2 of the epoxy resin D, the epoxy resin B, and the curing agent C was outside the predetermined range, exhibited poor screen printability.

Comparative Example 7, in which the total amount 1 of the epoxy resin A, the epoxy resin B, and the curing agent C was outside the predetermined range, exhibited poor screen printability and adhesiveness.

Comparative Example 8, in which the mass ratio [{C/(A or D)+B}] of the curing agent C with respect to the total amount of the epoxy resin A or the epoxy resin D and the epoxy resin B was outside of the predetermined range, exhibited high resistance and poor adhesiveness.

Comparative Examples 9 and 10, in which the mass ratio [(A or D)/B] of the epoxy resin A or the epoxy resin D to the epoxy resin B was outside the predetermined range, exhibited poor screen printability.

In contrast, the composition of an embodiment of the present technology excelled in screen printability, low resistance, and adhesiveness to a substrate.

1. An electrically conductive composition comprising:
electrically conductive particles;
an epoxy resin A that is a solid at 25° C. and has an epoxy equivalent weight of from 400 g/eq to less than 1500 g/eq, or an epoxy resin D that is a solid at 25° C. and has an epoxy equivalent weight of from 1500 g/eq to less than 3500 g/eq;
an epoxy resin B that is a liquid at 25° C. and has an epoxy equivalent weight of less than 400 g/eq;
a curing agent C; and
a solvent;
a total amount 1 of the epoxy resin A, the epoxy resin B, and the curing agent C being from 3 parts by mass to 10 parts by mass per 100 parts by mass of the electrically conductive particles, or a total amount 2 of the epoxy resin D, the epoxy resin B, and the curing agent C being from 3 parts by mass to less than 6 parts by mass per 100 parts by mass of the electrically conductive particles;
a mass ratio [(A or D)/B] of the epoxy resin A or the epoxy resin D to the epoxy resin B being from 20/80 to 80/20; and
a mass ratio [C/{(A or D)+B}] of the curing agent C to a total amount of the epoxy resin A or the epoxy resin D and the epoxy resin B being from 2/98 to 10/90.

2. The electrically conductive composition according to claim 1, wherein a softening point of the epoxy resin A is lower than 115° C.

3. The electrically conductive composition according to claim 1, wherein a softening point of the epoxy resin D is from 115° C. to 150° C.

4. The electrically conductive composition according to claim 1, wherein a viscosity at 25° C. of the epoxy resin B is from 15 to 5000 mPa·s.

5. The electrically conductive composition according to claim 1, wherein the electrically conductive particles are at least one type selected from the group consisting of silver powder, copper powder, and silver coated electrically conductive powder coated with silver on at least a portion of a surface.

6. The electrically conductive composition according to claim 1, wherein the electrically conductive particles comprise flake-shaped particles E having a specific surface area of from 0.2 to 1.0 m²/g and spherical particles F having a specific surface area of from 0.5 to 1.6 m²/g; and
an average specific surface area of the electrically conductive particles is from 0.5 to 0.8 m²/g.

7. The electrically conductive composition according to claim 1, wherein the total amount 1 is from 3 to 7.0 parts by mass per 100 parts by mass of the electrically conductive particles, or the total amount 2 is from 5.0 to 5.4 parts by mass per 100 parts by mass of the electrically conductive particles.

8. The electrically conductive composition according to claim 1, wherein the epoxy resin B is only a polyhydric alcohol glycidyl-type epoxy resin, and
the total amount 2 is from 4.0 to 5.4 parts by mass per 100 parts by mass of the electrically conductive particles.

9. The electrically conductive composition according to claim 2, wherein the total amount 1 is from 3 to 7.0 parts by mass per 100 parts by mass of the electrically conductive particles, or the total amount 2 is from 5.0 to 5.4 parts by mass per 100 parts by mass of the electrically conductive particles.

10. The electrically conductive composition according to claim 2, wherein the epoxy resin B is only a polyhydric alcohol glycidyl-type epoxy resin, and
the total amount 2 is from 4.0 to 5.4 parts by mass per 100 parts by mass of the electrically conductive particles.

11. The electrically conductive composition according to claim 3, wherein the total amount 1 is from 3 to 7.0 parts by mass per 100 parts by mass of the electrically conductive particles, or the total amount 2 is from 5.0 to 5.4 parts by mass per 100 parts by mass of the electrically conductive particles.

12. The electrically conductive composition according to claim 3, wherein the epoxy resin B is only a polyhydric alcohol glycidyl-type epoxy resin, and
the total amount 2 is from 4.0 to 5.4 parts by mass per 100 parts by mass of the electrically conductive particles.

13. The electrically conductive composition according to claim 4, wherein the total amount 1 is from 3 to 7.0 parts by mass per 100 parts by mass of the electrically conductive particles, or the total amount 2 is from 5.0 to 5.4 parts by mass per 100 parts by mass of the electrically conductive particles.

14. The electrically conductive composition according to claim 4, wherein the epoxy resin B is only a polyhydric alcohol glycidyl-type epoxy resin, and
the total amount 2 is from 4.0 to 5.4 parts by mass per 100 parts by mass of the electrically conductive particles.

15. The electrically conductive composition according to claim 5, wherein the total amount 1 is from 3 to 7.0 parts by mass per 100 parts by mass of the electrically conductive particles, or the total amount 2 is from 5.0 to 5.4 parts by mass per 100 parts by mass of the electrically conductive particles.

16. The electrically conductive composition according to claim 5, wherein the epoxy resin B is only a polyhydric alcohol glycidyl-type epoxy resin, and
the total amount 2 is from 4.0 to 5.4 parts by mass per 100 parts by mass of the electrically conductive particles.

17. The electrically conductive composition according to claim 6, wherein the total amount 1 is from 3 to 7.0 parts by mass per 100 parts by mass of the electrically conductive particles, or the total amount 2 is from 5.0 to 5.4 parts by mass per 100 parts by mass of the electrically conductive particles.

18. The electrically conductive composition according to claim 6, wherein the epoxy resin B is only a polyhydric alcohol glycidyl-type epoxy resin, and
the total amount 2 is from 4.0 to 5.4 parts by mass per 100 parts by mass of the electrically conductive particles.
